(19) United States
(12) Patent Application Publication
(10) Pub. No.: US 2013/0320465 A1
(43) Pub. Date: Dec. 5, 2013

(54) THIN MEMS MICROPHONE MODULE

(71) Applicants: Chao-Ching HUANG, Taichung City (TW); Ju-Mei Lu, Penghu County (TW); Hung-Jen Chen, Hsinchu City (TW); Kuan-Hsun Chiu, Taichung City (TW)

(72) Inventors: Chao-Ching HUANG, Taichung City (TW); Ju-Mei Lu, Penghu County (TW); Hung-Jen Chen, Hsinchu City (TW); Kuan-Hsun Chiu, Taichung City (TW)

(73) Assignee: Merry Electronics Co., Ltd., Taichung City (TW)

(21) Appl. No.: 13/483,352

(22) Filed: May 30, 2012

(51) Int. Cl. H01L 29/84

(52) U.S. Cl. 257/416; 257/E29.324

(57) ABSTRACT

A MEMS microphone module includes a first circuit board and a second circuit board attached to the first circuit board. A MEMS chip and an ASIC chip are respectively received in one of two concavities of the first circuit board. A first ground layer of the first circuit board and a second ground layer of the second circuit board are electrically coupled to each other to define a ground shielding structure. By this way, an EMI shielding can be applied by the ground shielding structure to the MEMS chip and the ASIC chip.

### BACKGROUND OF THE INVENTION

1. Field of the Invention

The present invention relates generally to a microphone module of micro-electro-mechanical system (hereinafter referred to as “MEMS”) and more particularly, to a MEMS microphone module that has a reduced overall package size.

2. Description of the Related Art

As shown in FIG. 1, a conventional MEMS microphone module 10 includes a circuit board 11, a MEMS chip 12 mounted to the circuit board 11, an application-specific integrated circuit (hereinafter referred to as “ASIC”) chip 13 mounted to the circuit board 11 and electrically coupled to the MEMS chip 12 through a wire 15, and a metal lid 14 covered on the circuit board 11 to define a chamber 16 for accommodation of the MEMS chip 12 and the ASIC chip 13. By this way, an electromagnetic interference (hereinafter referred to as “EMI”) shielding can be applied by the metal lid 14 to the MEMS chip 12 and the ASIC chip 13.

However, the chamber 16 defined between the metal lid 14 and the circuit board 11 must have enough volume to contain the wire 15, such that the metal lid 14 should be required to maintain a certain height. Therefore, it can be seen that the overall package size of the conventional MEMS microphone module 10 is difficult to be reduced.

### SUMMARY OF THE INVENTION

The present invention has been accomplished in view of the above-noted circumstances. It is therefore the primary objective of the present invention to provide a MEMS microphone module, which has a small package height so as to have a reduced overall package size.

To achieve the above-mentioned objective, the MEMS microphone module provided by the present invention comprises a first circuit board, a MEMS chip received in a first concavity of the first circuit board, a second circuit board covered on the first circuit board and having an acoustic hole corresponding to the MEMS chip, a second signal layer electrically coupled to a first signal layer of the first circuit board and the MEMS chip, and a second ground layer electrically coupled to a first ground layer of the first circuit board, and an application-specific integrated circuit (ASIC) chip mounted to the second circuit board in such a way that the ASIC chip is accommodated in a second concavity of the first circuit board and electrically coupled to the first signal layer of the first circuit board. A ground shielding structure is defined by the first ground layer of the first circuit board and the second ground layer of the second circuit board to apply an EMI shielding to the MEMS chip and the ASIC chip.

By means of this design, the MEMS microphone module of the present invention is assembled by the two circuit boards and provided with the EMI shielding structure by the internal ground layers of the circuit boards, such that the MEMS microphone module of the present invention can have it's a small package height to attaining the purpose of reducing its overall package volume.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a cross-sectional view of a MEMS microphone module in accordance with a prior art;

FIG. 2 is a schematic drawing showing a method of manufacturing a MEMS microphone module in accordance with a preferred embodiment of the present invention; and

FIG. 3 is a cross-sectional view of the MEMS microphone module in accordance with the preferred embodiment of the present invention.

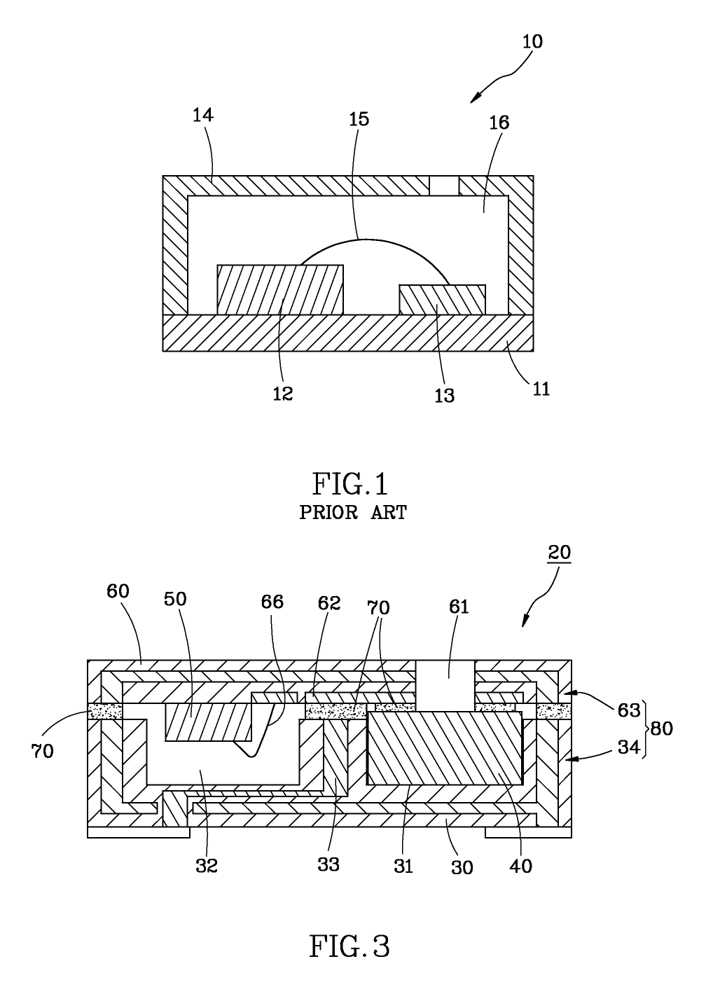

### DETAILED DESCRIPTION OF THE INVENTION

Referring to FIG. 3, a micro-electro-mechanical system (MEMS) microphone module 20 provided by a preferred embodiment of the present invention comprises a first circuit board 30, a MEMS chip 40, an application-specific integrated circuit (ASIC) chip 50, and a second circuit board 60.

The first circuit board 30 has a first concavity 31 at the top side thereof, a second concavity 32 at the top side thereof spaced from the first concavity 31. Further, a first signal layer 33 and a first ground layer 34 embedded in the first circuit board 30.

The MEMS chip 40 is received in the first concavity 31 of the first circuit board 30 and attached on the bottom of the first concavity 31.

The second circuit board 60 is covered on the top side of the first circuit board 30, and has a bottom side thereof for attachment of the ASIC chip 50 accommodated in the second concavity 32 of the first circuit board 30. The second circuit board 60 includes an acoustic hole 61 corresponding to the MEMS chip 40, and a second signal layer 62 electrically coupled to the first signal layer 33 of the first circuit board 30 and the MEMS chip 40 through a conductive adhesive 70 and meanwhile electrically coupled to the ASIC chip 50 through a wire 66. Further, a second ground layer 63 of the second circuit board 60 is electrically coupled to the first ground layer 34 of the first circuit board 30 through a conductive adhesive 70, such that a ground shielding structure 80 is defined by the first and second ground layers 34 and 63 to apply an EMI shielding to the MEMS chip 40 and the ASIC chip 50.

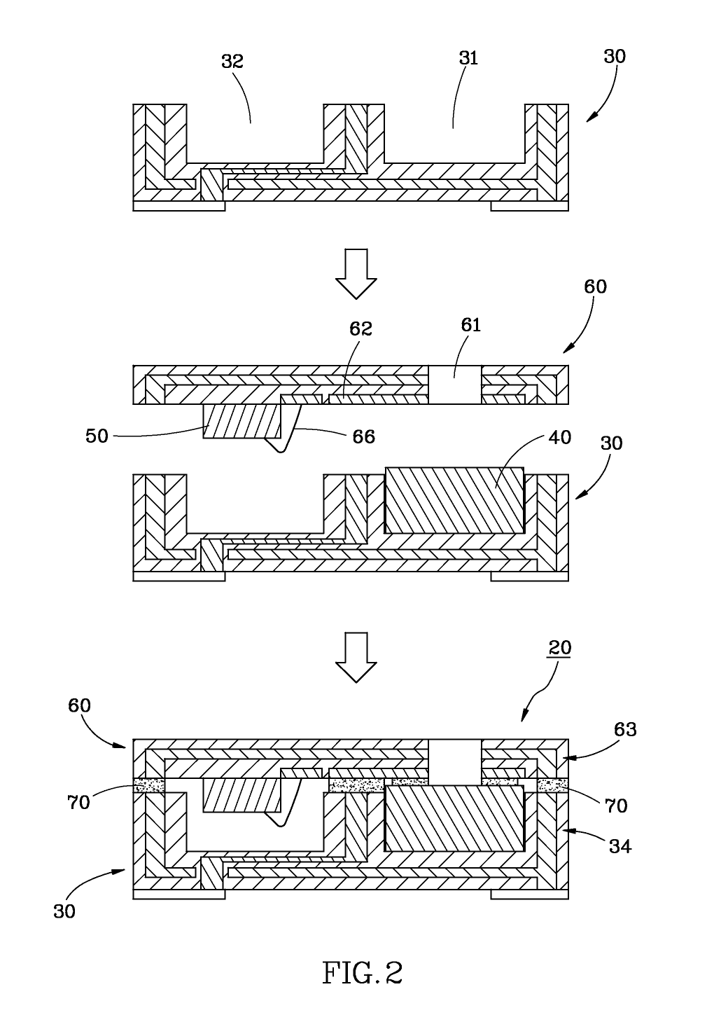

FIG. 2 shows the method of manufacturing the MEMS microphone module 20 of the present invention, including the steps of: forming the first and second concavities 31 and 32 on the top side of the first circuit board 30 in which the wire layout and the embedded layer have been provided by mechanical processing, and then respectively attaching the MEMS chip 40 and the ASIC chip 50 to the bottom of the first concavity 31 of the first circuit board 30 and the bottom side of the second circuit board 60 in which the wire layout and the embedded layer have also been provided, and then electrically coupling the ASIC chip 50 to the second signal layer 62 of the second circuit board 60 through the wire 66, and then forming the acoustic hole 61 in the second circuit board 60 by mechanical processing, and then attaching the second circuit board 60 on the top side of the first circuit board 30 through the conductive adhesive 70 for enabling the first and second ground layers 34 and 63 to be electrically coupled to each other. By means of the aforesaid steps, the MEMS microphone module 20 of the present invention is manufactured.

When the MEMS microphone module 20 of the present invention is used, the MEMS chip 40 receives the external sounds through the acoustic hole 61 of the second circuit board 60 and converts the sound waves into capacity variations, and then the ASIC chip 50 converts the capacity variations into an electrical signal through the second signal layer 62 of the second circuit board 60, and then the ASIC chip 50 transmits the electrical signal to a signal processor or an amplifier through the first and second signal layers 33 and 62.

As indicated above, the MEMS microphone module 20 of the present invention is assembled by means of the attachment of the two circuit boards 20 and 60, and creates the EMI shielding through the internal ground layers 34 and 63 of the circuit boards 20 and 60, such that the MEMS microphone module 20 of the present invention can have a small package height to attaining the purpose of reducing its overall package volume.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A MEMS microphone module comprising:
a first circuit board has a first concavity, a second concavity spaced from the first concavity, a first signal layer, and a first ground layer;
a MEMS chip received in the first concavity of the first circuit board;
a second circuit board covered on the first circuit board, and having an acoustic hole, a second signal layer, and second ground layer; and
an ASIC chip mounted to the second circuit board and received in the second concavity of the first circuit board;
wherein the acoustic hole of the second circuit board corresponds to the MEMS chip, and the second signal layer of the second circuit board is electrically coupled to the first signal layer of the first circuit board, the MEMS chip, and the ASIC chip, and the second ground layer of the second circuit board is electrically coupled to the first ground layer of the first circuit board to define a ground shielding structure for providing an AMI shielding to the MEMS chip and the ASIC chip.

2. The MEMS microphone module of claim 1, wherein the MEMS chip is attached on a bottom of the first concavity of the first circuit board.

3. The MEMS microphone module of claim 1, wherein the ASIC chip is electrically coupled to the second signal layer of the second circuit board through a wire.

4. The MEMS microphone module of claim 1, wherein the first signal layer of the first circuit board is electrically coupled to the second signal layer of the second circuit board through a conductive adhesive.

5. The MEMS microphone module of claim 1, wherein the first ground layer of the first circuit board is electrically coupled to the second ground layer of the second circuit board through a conductive adhesive.

6. The MEMS microphone module of claim 1, wherein the MEMS chip is electrically coupled to the second signal layer of the second circuit board though a conductive adhesive.

7. The MEMS microphone module of claim 1, wherein the MEMS chip is attached on a bottom of the first concavity of the first circuit board; the ASIC chip is electrically coupled to the second signal layer of the second circuit board through a wire; and wherein the first signal layer of the first circuit board is electrically coupled to the second signal layer of the second circuit board through a conductive adhesive.
